(19) United States
(12) Patent Application Publication
(10) Pub. No.: US 2011/0163341 A1
(43) Pub. Date: Jul. 7, 2011

(54) LIGHT OUTPUT DEVICE AND ASSEMBLY METHOD

(75) Inventors: Rob Franciscus Maria Van Elmpt, Eindhoven (NL); Mark Eduard Johan Sipkes, Eindhoven (NL)

(73) Assignee: KONINKLIJKE PHILIPS ELECTRONICS N.V., EINDHOVEN (NL)

(21) Appl. No.: 13/002,704

(22) PCT Filed: Jul. 6, 2009
(86) PCT No.: PCT/IB2009/052934

§ 371 Date: Mar. 24, 2011

(30) Foreign Application Priority Data
Jul. 11, 2008 (EP) 08160171.8

(51) Int. Cl. H01L 33/58

(52) U.S. Cl. 257/98; 438/27; 257/E33.073

(57) ABSTRACT

The present invention relates to a light output device (10) comprising a heat sink (12); a substrate (14) with at least one light emitting element (24) arranged thereon; and an optical component (16), wherein the optical component is mounted to the heat sink by means of a bayonet type mechanism, and wherein the substrate is fixed between the heat sink and the optical component. The present invention also relates to a method of assembling such a light output device.

### FIELD OF THE INVENTION

The present invention relates to a light output device, in particular a light output device comprising at least one light emitting diode (LED), as well as a method of assembling such a light output device.

### BACKGROUND OF THE INVENTION

Generally, printed circuit boards (PCBs) with LEDs are often glued, screwed or clamped to a heat sink to ensure thermal contact and sufficient heat conduction away from the LEDs. Also, often optics are placed over the LEDs to provide a desired radiation pattern or to protect the LED.

U.S. Pat. No. 7,348,604 (Matheson) discloses a light-emitting module comprising heat dissipation element, a substrate coupled to one or more light emitting elements, and a housing element including fastening means for coupling the housing element to the heat dissipation element, the substrate allegedly being enclosed between the heat dissipation element and the housing element. The housing element is provided with an optical element, and it is flexible to be slid over the heat dissipation element and clutch the latter as it resumes its unstrained shape.

A drawback with the solution presented in Matheson is that the flexible property of the housing element imposes design constraints on the housing element with respect to material and shape selection.

### SUMMARY OF THE INVENTION

It is an object of the present invention to at least partly overcome this drawback, and to provide an improved light output device.

This and other objects that will be apparent from the following description are achieved by a light output device, and a method of assembling such a light output device, according to the appended independent claims.

According to an aspect of the present invention, there is provided a light output device, comprising: a heat sink; a substrate with at least one light emitting element arranged thereon; and an optical component, wherein the optical component is mounted to the heat sink by means of a bayonet type mechanism, and wherein the substrate is fixed between the heat sink and the optical component.

A bayonet type mechanism may generally be defined as an arrangement for fastening with a short rotational movement two connecting parts of rotary symmetrical character to each other. By using a bayonet type mechanism, simply twisting the optical component may fixate the optical component in the right position and also fixate the substrate to the heat sink. The latter ensures thermal contact between the substrate and the heat sink. Fixation of the substrate to the heat sink is thus advantageously carried out without having to use flexible elements, or screws, glue or other additional components. Also, the substrate may be forced to the heat sink where it is needed: namely around the at least one LED.

In one embodiment, the bayonet type mechanism comprises two opposite lateral members protruding from the optical component and two opposite grooves in the heat sink adapted to receive said protruding members, as the optical component is rotated appropriately. The optical element may for instance include a base plate having the shape of a rectangle with two diagonally opposite rounded corners, and the heat sink may be formed as a profiled channel with two longitudinal, inner grooves. Thus, the function of fixating the substrate to the heat sink is integrated mainly in the optical element.

Preferably, the substrate is a printed circuit board, the optical component is a collimating lens, and the at least one light emitting element is at least one light emitting diode (chip or package). Benefits of LEDs include high efficiency, long useful life, etc. Alternative substrates include, but are not limited to, a wired circuit board. Alternative optical components include, but are not limited to, a protective transparent or translucent cover, a diffusing cover, a lens, a reflector, etc. Alternative light emitting elements include, but are not limited to, organic light emitting diodes (OLEDs), laser diodes, etc.

According to another aspect of the present invention, there is provided a method of assembling a light output device, the method comprising: providing a heat sink; placing a substrate with at least one light emitting element arranged thereon on the heat sink; and mounting an optical component to the heat sink by means of a bayonet mechanism such that the substrate is fixed between the heat sink and the optical component. In one embodiment, the bayonet type mechanism comprises two opposite lateral members protruding from the optical component and two opposite grooves in the heat sink, wherein mounting the optical component to the heat sink comprises rotating the optical component in relation to the heat sink such that the protruding members are received in the grooves. In particular, the optical component is preferably mounted to the heat sink by rotating it about 30-150 degrees, preferably about 45 degrees, i.e. a short rotary movement, compared to for instance a screw fitting which requires a long rotary movement for a similar function. Moreover, this aspect exhibits similar advantages and may exhibit similar features as the aspect discussed above.

### BRIEF DESCRIPTION OF THE DRAWINGS

These and other aspects of the present invention will now be described in more detail, with reference to the appended drawings showing currently preferred embodiments of the invention.

FIGS. 1a-5b are perspective views and side views, respectively, illustrating steps of assembling a light output device according to an embodiment of the present invention.

FIG. 6a is a perspective view and FIG. 6b is a cross-sectional side view of an optical element of the present light output device.

### DETAILED DESCRIPTION

A light output device 10 according to an embodiment of the present invention will now be described with reference to the appended drawings.

The light output device 10 comprises a heat sink 12, a PCB 14, and an optical component 16.

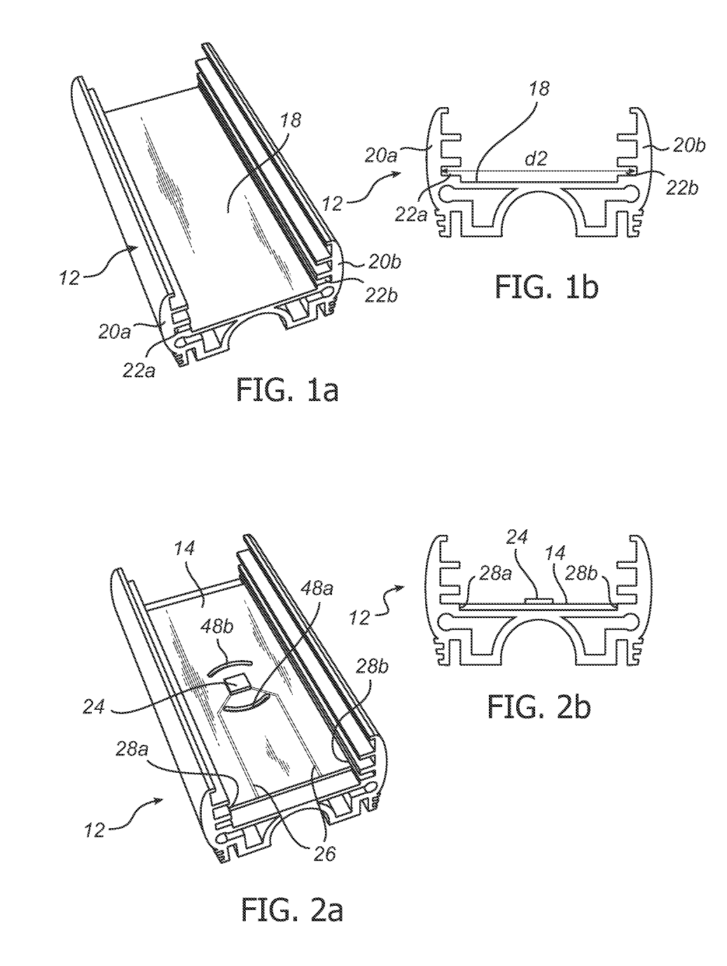

The heat sink 12 is preferably made of a material with high thermal conductivity, such as metal, in particular aluminum. The present heat sink 12 is a profiled channel having a base portion 18 and two side wall portions 20a, 20b. Two opposite grooves 22a, 22b run along the inside of the wall portion 20a, 20b near the base portion 18, as illustrated in e.g. FIGS. 1a-1b. The heat sink 12 may optionally comprise a plurality of fins for enhanced heat dissipation.

The PCB 14 comprises at least one LED 24 thermally connected thereto. The LED 24 may be an LED package, or a chip or die mounted directly on the PCB 14. The PCB 14 further comprises electrically conductive traces 26 or the like for electrically connecting the LED(s) 24 to a power source (not shown), for activation of the LED(s) 24. The PCB 14 rests, preferably directly, on the base portion 18 between the two wall portions 20a, 20b of the heat sink 12. Also, opposite edges 28a, 28b of the PCB 14 may abut the inside of the wall portions 20a, 20b, as illustrated in e.g. FIG. 2b, thereby preventing movement of the PCB 14 transversal to the wall portions 20a, 20b.

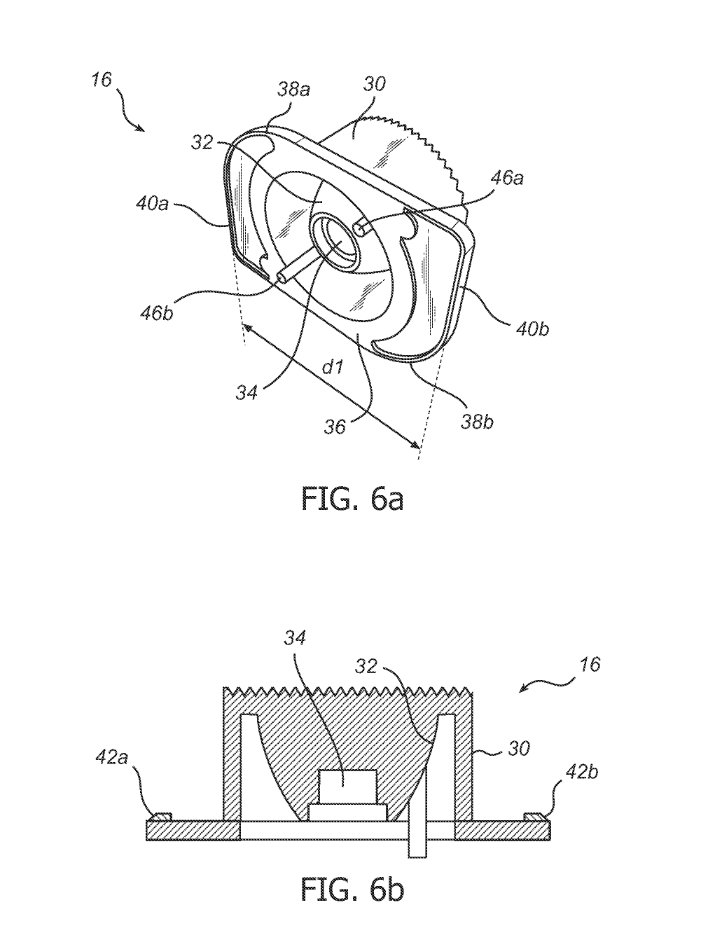

The optical component 16 comprises a body portion made of e.g. polycarbonate or PMMA with a cylindrical outside 30 and a sloping inside 32 (see FIGS. 6a-6b), the latter serving as a collimating reflector based on total internal reflection (TIR). The optical component 16 further comprises a central opening 34 where the at least one LED 14 is to be placed. Also, the optical component 16 comprises a base plate 36 facing the base portion 18 of the heat sink 12. The base plate 36 is substantially rigid, and the optical component 16 including the base plate 36 may be integrally formed in one piece. The base plate 36 has the overall shape of a rectangle with two rounded corners 38a, 38b, as illustrated. The (perpendicular) distance d1 between the shorter sides 40a, 40b of the rectangular base plate 36 is substantially equal to the distance d2 between the bottom of the grooves 22a, 22b, whereas the corresponding distance between the other sides of the rectangular base plate 34 is shorter. Further, the thickness of the base plate 36 is preferably selected such that it may be jammed in the grooves 22a, 22b. Alternatively, wedges 42a, 42b may be provided at the shorter sides 40a, 40b for this purpose.

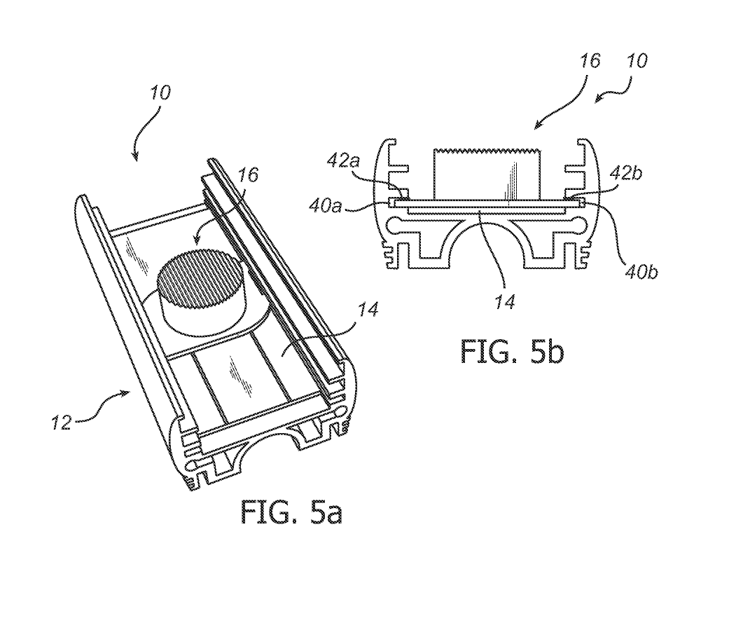

In the state illustrated in FIGS. 5a and 5b, the optical component 16 is placed over the PCB 14 and rotated such that at least portions of the shorter sides 40a, 40b of the rectangular base plate 36 are received in the grooves 22a, 22b. This prevents movement of the optical component 16 transversal to the base portion 18 of the heat sink. Further, movement of the optical component 16 transversal to the wall portions 20a, 20b is prevented. The connection between the optical component 16a and the heat sink 12 additionally applies a pressure or force to the PCB 14, which PCB 14 is inlayed or mechanically sandwiched between the optical component 16 and the heat sink 12, such that the PCB 14 is pressed against the heat sink 12, thereby fixating the PCB 14 to the heat sink 12 and establishing a desired level of thermal contact between the PCB 14 and the heat sink 12. This may be achieved by appropriately selecting the thickness of the PCB 14 in relation to the distance between the base portion 18 and the grooves 22a, 22b of the heat sink 12. No additional components except of the optical component 16 are needed to fixate the PCB 14 to the heat sink 12. Also, the optical component 16 designed as described above may seal the LED 24 from the outside. This beneficially allows filling the device or module 10 outside the optical component 16 with a filling/potting material (not shown) to protect the LED 24 from water or moisture, without the filling/potting material entering the central opening or optical cavity 34 from the underside.

Longitudinal movement of the PCB 14 and the optical component 16 along the wall portions 20a, 20b is prevented as portions of the base plate 34 are jammed in the grooves 22a, 22b. End caps may optionally be used.

Upon operation of the light output device 10, current is supplied to the LED(s) 24 via the electrically conductive traces 26 of the PCB 14, whereby the at least one LED 24 emits light. The radiation pattern of the emitted light may be shaped by the optical component 16. Here, the emitted light is collimated. Further, heat generated by the LED(s) 24 is effectively transferred by direct thermal contact from the PCB 14 to the heat sink 12, for cooling of the LED(s) 24.

A method of assembling the light output device 10 according to an embodiment of the present invention will now be described.

First, in step S1 (FIGS. 1a-1b), the heat sink 12 is provided.

Then, in step S2 (FIGS. 2a-2b), the PCB 14 is placed on the base portion 18 between the side wall portions 20a, 20b of the heat sink 12. The at least one LED 24 is preferably mounted to the PCB 14 prior to the PCB 14 being placed on the heat sink 12, but it could alternatively be mounted to the PCB 14 subsequent to the PCB 14 being placed on the heat sink 12.

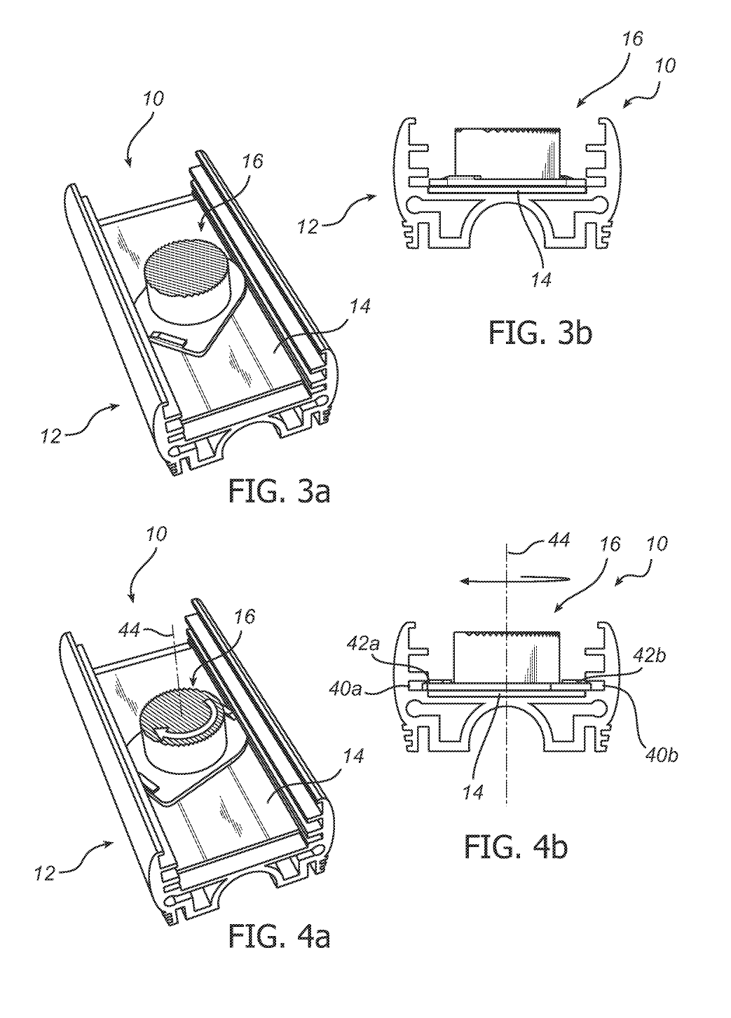

Then, in step S3 (FIGS. 3a-3b), the optical component 16 is introduced, e.g. from above, into the space between the wall portions 20a, 20b and placed on the PCB 14, with the opening 34 aligned with the at least one LED 24. Here, the optical component 16 is oriented such that the sides of the base plate 36 are oriented at about 45 degrees to the side wall portions 20a, 20b of the heat sink 12, as illustrated.

Thereafter, the optical component 16 is rotated (step S4) around a central axis 44 of the optical component 16, which axis 44 is perpendicular to the plane of the base portion 18 of the heat sink 12. The optical component 16 may be rotated manually or automatically by means of a machine.

In FIGS. 4a-4b, the optical element 16 is rotated clockwise about 22.5 degrees from its initial position, whereas in FIGS. 5a-5b the optical element 16 is in its final position, where it is rotated clockwise about 45 degrees from its initial position. In this final position or state, as discussed above, at least portions of the shorter sides 40a, 40b of the rectangular base plate 36 are received in the grooves 22a, 22b, whereby the optical element 16 is locked in the heat sink 12, and the PCB 14 is fixed between the heat sink 12 and the optical component 16.

As appreciated, the base plate 36 should be sized so as to first allow the optical component 16 to be introduced into the space between the wall portions 20a, 20b and then allow it to rotate the full 45 degrees when the base plate 36 is in level with the grooves 22a, 22b. Further, the optical element 16 may be provided with protrusions mating with at least one slit in the PCB 14, or vice versa, for guiding the optical element 16 on the PCB 14, ensuring proper alignment of the optical element 16 on the PCB 14 and also controlling the rotary motion of the optical element 16 on the PCB 14. The protrusion may for instance be two downright pins 46a, 46b extending from the underside of the optical element 16 (see FIG. 6a), whereas the at least one slit may be two curved slits 48a, 48b (see FIG. 2a) provided in the PCB 14 around the LED 24. This solution is easier in production, compared to a solution where the PCB has the pins and the optical element has the recess(es). The length of the curved slits 48a, 48b should preferably match the angle of rotation that is needed between the initial state and the final state of the optical element 16. At an angle of rotation equal to about 45 degrees as above, the two curved slits 48a, 48b may be sufficiently short to allow some place on the PCB 14 for the traces 26 and maintain an adequate mechanical stiffness of the PCB 14.

The device and method described above may beneficially be used in all applications that use LEDs on a PCB, combined with an optical component.

The person skilled in the art realizes that the present invention by no means is limited to the preferred embodiments described above. On the contrary, many modifications and variations are possible within the scope of the appended claims. For instance, several PCBs and optical components could be arranged on a single heat sink.

1. A light output device, comprising:
a heat sink;
a substrate having at least one light emitting element arranged thereon; and
an optical component,
wherein the optical component and said heat sink are arranged such that said optical component is mounted to the heat sink by means of a twist-lock mechanism, and the substrate is retained between the heat sink and the optical component.

2. A light output device according to claim 1, wherein the twist-lock mechanism comprises two opposite lateral members protruding from the optical component and two opposite grooves formed in the heat sink for receiving said protruding members.

3. A light output device according to claim 1, wherein the substrate is a printed circuit board.

4. A light output device according to claim 1, wherein the optical component is a collimating lens.

5. A light output device according to claim 1 wherein the at least one light emitting element is at least one light emitting diode.

6. A method of assembling a light output device, the method comprising:
providing a heat sink;
placing a substrate with at least one light emitting element arranged thereon on the heat sink; and
mounting an optical component to the heat sink by means of a twist-lock mechanism such that the substrate is retained between the heat sink and the optical component.

7. A method according to claim 6, wherein the twist-lock mechanism comprises two opposite lateral members protruding from the optical component and two opposite grooves in the heat sink, and wherein mounting the optical component to the heat sink comprises axially rotating the optical component in relation to the heat sink such that the protruding members are received in the grooves.

8. A method according to claim 7, wherein the optical component is rotated about 30 to 150 degrees relative to the heat sink.
